(19) United States
(12) Patent Application Publication
(10) Pub. No.: US 2007/0089032 A1
(43) Pub. Date: Apr. 19, 2007

(54) Memory system anti-aliasing scheme

(75) Inventors: James W. Alexander, Aloha, OR (US); Joaquin B. Romera, Portland, OR (US); Rajat Agarwal, Beaverton, OR (US); Thomas Holman, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: INTEL CORPORATION

(21) Appl. No.: 11/240,823

(22) Filed: Sep. 30, 2005

(51) Int. Cl. G11C 29/00

(52) U.S. Cl. 714/763

(57) ABSTRACT

Embodiments of the invention are generally directed to systems, methods, and apparatuses for a memory device anti-aliasing scheme. In an embodiment, a memory controller includes an error check agent to receive a codeword from a rank of memory and to provide an error indication in response to detecting a correctable adjacent-symbol-pair-error the rank of memory. An error counter may be coupled with the error check agent to increment towards a threshold value in response to the error indication from the error check agent. In an embodiment, a faulty memory device marker agent coupled with the error counter provides a faulty memory device marker to the error check agent, if the error counter exceeds the threshold value. Other embodiments are described and claimed.

### TECHNICAL FIELD

Embodiments of the invention generally relate to the field of data processing and, more particularly, to systems, methods, and apparatuses for a memory device anti-aliasing scheme.

### BACKGROUND

Memory content errors can be classified as either persistent errors or transient errors. Persistent errors are typically caused by physical malfunctions such as the failure of a memory device or the failure of a socket contact. Transient errors, on the other hand, are usually caused by energetic particles (e.g., neutrons) passing through a semiconductor device, or by signaling errors that generate faulty bits at the receiver. These errors are called transient (or soft) errors because they do not reflect a permanent failure. A “faulty bit” refers to a bit that has been corrupted by a memory content (or signaling) error.

Many memory systems include error correction mechanisms that can detect and/or correct a faulty bit (or bits). These mechanisms typically involve adding redundant information to data to protect it against faults. One example of an error correction mechanism is a conventional error correction code. Conventional error correction codes check data read from memory to determine whether it contains a faulty bit (or bits). If the data does include a faulty bit, then the conventional error code may provide an error indication.

The error indication provided by the error correction code is not always correct. The reason for this is that error correction codes are designed (sometimes through a specification) to detect and correct errors having certain mathematical error weights. If an error correction code receives data having an error that exceeds the error weight for which the error correction code is specified, then the error indication provided by the error correction code could be incorrect. The term “alias” refers to an error indication provided by an error correction code that is incorrect.

One approach to determining whether an error indication is an alias or a valid error is to retry certain types of detected errors. The term “retry” refers to rereading data from memory. The retry mechanisms used to reduce aliasing in conventional error correction codes are typically complex.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a high-level block diagram illustrating selected aspects of a computing system implemented according to an embodiment of the invention.

FIG. 2 is a block diagram of selected aspects of a memory system, implemented to provide a memory device anti-aliasing scheme according to an embodiment of the invention.

FIG. 3 is a block diagram illustrating selected aspects of a rank of memory implemented according to an embodiment of the invention.

FIG. 4 is a flow diagram illustrating selected aspects of a memory device anti-aliasing scheme according to an embodiment of the invention.

FIG. 5 illustrates selected aspects of processing a codeword having a memory device identified as faulty, according to an embodiment of the invention.

FIGS. 6A and 6B are block diagrams illustrating selected aspects of computing systems.

### DETAILED DESCRIPTION

Embodiments of the invention are generally directed to systems, methods, and apparatuses for a memory device anti-aliasing scheme. An “anti-aliasing scheme” refers to a scheme for reducing the number of uncorrectable errors that a memory system aliases as correctable errors. In an embodiment, the complex multiple-retry scheme used in conventional error correction codes is replaced with a simpler scheme that uses an array of counters and a faulty memory device marker agent. In an embodiment, the array of counters includes an error counter and a decrement counter for each rank of memory. Each time the memory system detects a correctable adjacent-symbol-pair error in a rank of memory, an error counter associated with the rank of memory is incremented. If the error counter exceeds a threshold, the memory device in which the error appears may be marked as faulty. In an embodiment, subsequent correctable errors on that rank appearing in that memory device are treated as correctable errors. Subsequent correctable errors on that rank appearing in some other memory device will be treated as uncorrectable errors.

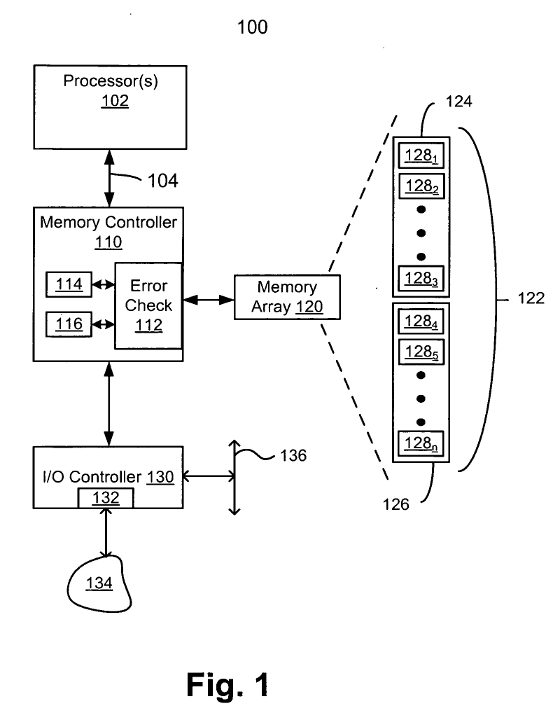

FIG. 1 is a high-level block diagram illustrating selected aspects of a computing system implemented according to an embodiment of the invention. Computing system 100 includes one or more processors 102. The term processor broadly refers to a physical processor and/or a logical processor. A physical processor includes, for example, a central processing unit, a microcontroller, a partitioned core, and the like. A logical processor refers, for example, to the case in which physical resources are shared by two or more threads and the architecture state is duplicated for the two logical processors. Examples of logical processors include threads, hyper-threads, bootstrap processors, and the like.

Processors 102 are coupled with memory controller 110 through processor bus 104. Memory controller 110 controls (at least partly) the flow of information between processors 102 and a memory subsystem. Memory controller 110 includes error check agent 112. In one embodiment, error check agent 112 is based, at least in part, on a single error correct, double error detect Hamming style code. In an alternative embodiment, error check agent 112 is based (at least partly) on a “b”-bit single device disable error correction code (SbEC-DED). In yet other alternative embodiments other and/or additional error correction codes may be used. The term “agent” broadly refers to a functional element of computing system 100. An agent may be implemented in hardware, software, firmware, or any combination thereof.

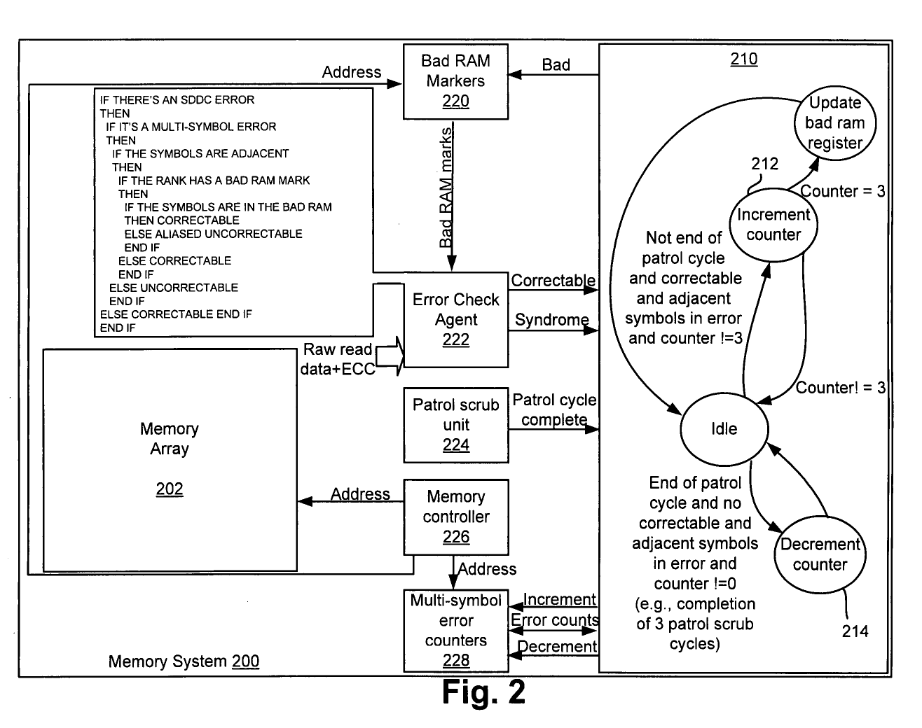

Memory controller 110 includes an array of error counters 114 and faulty memory device marker agent 116. In an embodiment, the array of error counters 114 includes an error counter and a decrement counter for each rank of memory in memory array 120. Faulty memory device marker agent 116 generates markers used by error check agent 112 to mark a memory device as faulty under certain conditions. As is further described below with reference to FIGS. 2-5, the array of counters 114 and faulty memory device marker agent 116 are part of a memory device anti-aliasing scheme.

Memory array 120 provides volatile memory for computing system 100. In one embodiment, memory array 120 includes one or more ranks of memory devices (or, for ease of reference, ranks) 122. The term rank refers to the set of memory devices that provide a codeword. A codeword includes both data bytes and the correction code that covers those data bytes. In one embodiment, rank 122 includes eighteen memory devices 128. In an alternative embodiment, rank 122 may include a different number of memory devices. The memory devices may be distributed across one or more memory modules 124 and 126. In an embodiment, memory modules 124 and 126 are dual inline memory modules (DIMMs).

Input/output (I/O) controller 130 controls, at least in part, the flow of information into and out of computing system 100. I/O controller 130 includes one or more wired or wireless network interfaces 132 to interface with network 134. In addition, I/O controller 130 includes one or more interfaces 136 to support the exchange of information over a variety of interconnects. These interfaces may support a variety of interconnect technologies including, for example, universal serial bus (USB), peripheral component interconnect (PCI), PCI express, and the like.

FIG. 2 is a block diagram of selected aspects of memory system 200, implemented according to an embodiment of the invention. Memory system 200 includes memory array 202, error counter array 228, faulty memory device marker agent 220, error check agent 222, patrol scrub unit 224, and memory controller 226. In an alternative embodiment, memory system 200 may include more elements, fewer elements, and/or different elements.

Memory array 202 provides one or more ranks of volatile memory for memory system 200. In one embodiment, a rank of memory includes 18 memory devices. The memory devices may be commodity-type dynamic random access memory (DRAM) such as Double Data Rate II (DDR2) DRAM. For example, the memory devices may be ×8 DRAMs. In an alternative embodiment, a different type of memory devices may be used. For ease of reference, the memory devices of memory array 202 may be referred to as random access memory (RAM). Similarly, faulty memory device marker agent 220 may be referred to as faulty RAM marker agent 220.

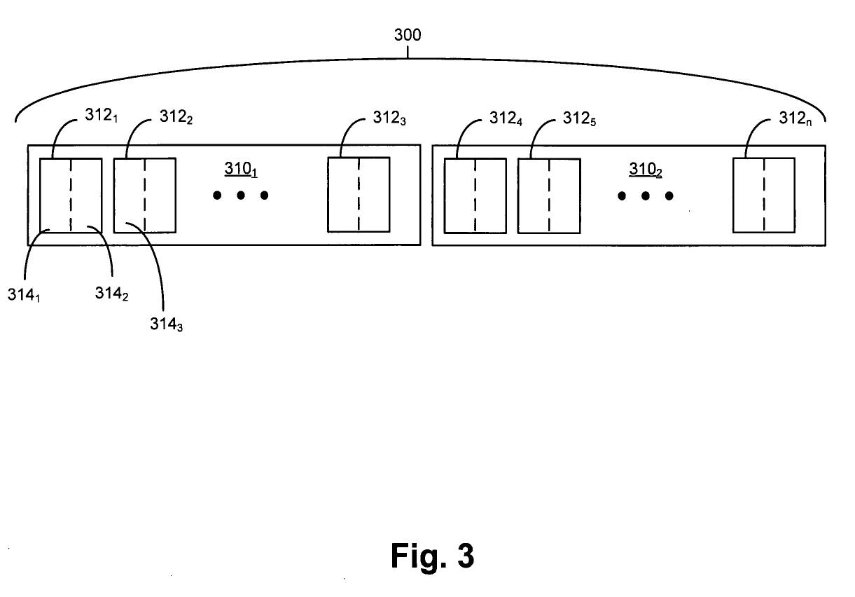

FIG. 3 is a high level block diagram illustrating a rank of memory implemented according to an embodiment of the invention. Rank 300 includes 18 memory devices 312 distributed across two memory modules 310. In an embodiment, memory devices 312 are ×8 DRAMs and memory modules 310 are DIMMs. In an alternative embodiment, different memory devices and/or different modules may be used. Similarly, rank 300 may include a different number of memory devices and/or a different number of DRAMs.

In an embodiment, each memory device 312 includes two symbols 314. A symbol is an element (e.g., an eight bit element) of a codeword. In an embodiment, a symbol can be either a data symbol or an ECC code symbol. A data symbol includes eight bits of data and an ECC code symbol includes eight bits of ECC code.

Adjacent symbols refer to symbols that are within the same memory device. For example, symbol 314₁ is adjacent to symbol 314₂. Symbol 314₃ is not, however, adjacent with symbol 314₂ because symbols 314₃ and 314₂ are not within the same memory device. A correctable adjacent-symbol-pair-error is a correctable error in which faulty bits in adjacent symbols are identified. For example, a correctable adjacent-symbol-pair-error is an error among any covered number of bits within adjacent symbols (e.g., symbols 314₁ and 314₂).

Referring again to FIG. 2, memory system 200 includes error check agent 222. Error check agent 222 receives codewords from memory array 202 and determines whether they contain an error. In one embodiment, error check agent 222 includes an implementation of a Hamming style error correction code. In an alternative embodiment, error check agent 222 may include an implementation of a different type of error correction code.

Patrol scrub unit 224 includes logic to periodically read the data stored in memory array 202. In addition, patrol scrub unit 224 may include logic to detect and correct errors that accumulate in memory array 202 due to, for example, neutron strikes. In an embodiment, the frequency of a patrol scrub is approximately once per 24 hours. In an alternative embodiment, the frequency of the patrol scrub may be different (and/or may be variable). In addition, the frequency of the patrol scrub may be programmable.

Array of counters 228 includes an array of counters that are used to track the number of certain kinds of errors that occur in memory array 202. In an embodiment, each rank of memory is associated with one or more counters in the array. Counters 210 illustrate the counters associated with a rank of memory according to an embodiment of the invention.

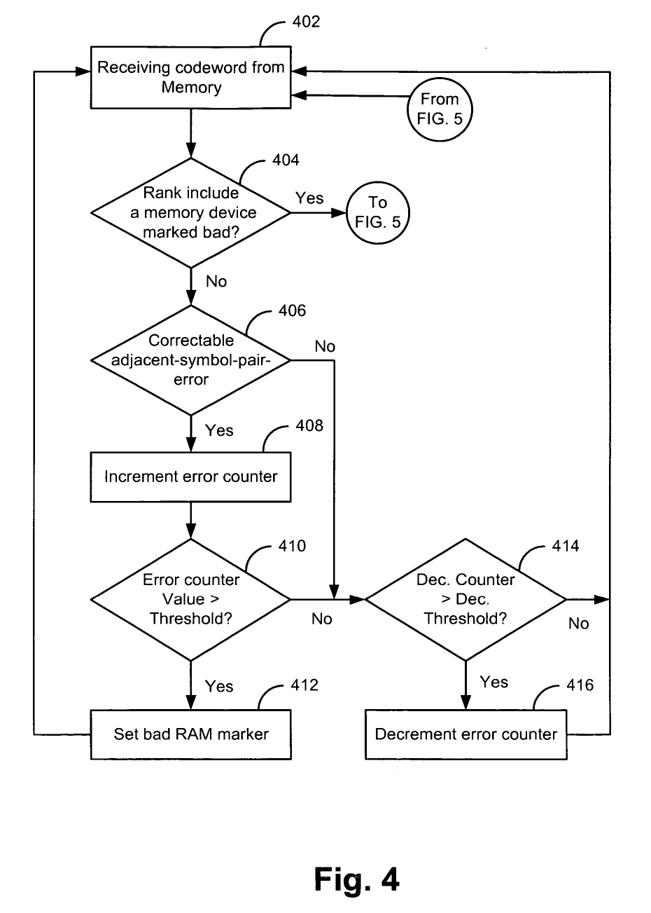

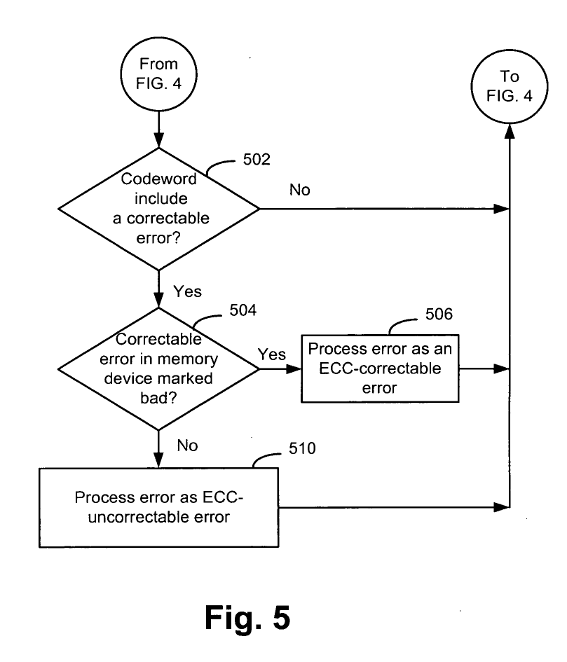

Counters 210 include error counter 212 and decrement counter 214. In an embodiment, error counter 212 is incremented when its associated rank of memory shows a correctable adjacent-symbol-pair-error. As is further described below, decrement counter 214 may decrement counter 212 in response to a decrement event (e.g., the completion of a patrol scrub). When error counter 212 exceeds a threshold, faulty RAM marker agent 220 marks the RAM containing the error as faulty. Subsequent correctable errors on that rank that appear in the RAM marked faulty are treated as correctable errors. Subsequent correctable errors on that rank that appear in a RAM that is not marked faulty are processed as uncorrectable errors. Selected processes associated with an anti-aliasing scheme based, at least in part, on counters is further described below with reference to FIGS. 4 and 5.

In an embodiment, there is a possibility that a fraction of the detected correctable adjacent-symbol-pair-errors are not caused by a faulty DRAM device. For example, bus transients (and other events) may generate multi-symbol errors. These bus transients (and other events) can lead to valid memory devices being falsely marked as faulty. In an embodiment, a “drip policy” is used to reduce the possibility that a valid memory device will be falsely marked as faulty. The term “drip policy” refers to occasionally decrementing the error counter.

In an embodiment, the drip policy is, at least in part, implemented with decrement counter 214. For example, in an embodiment, decrement counter 214 decrements error counter 212 in response to a decrement event. The decrement event may be associated with a periodic read of memory array 202 and/or it may be associated with the threshold value of counter 212. For example, if the threshold value is N, then counter 212 may be decremented after N patrol scrub cycles. In one embodiment, the threshold value is 3 and counter 212 is decremented after approximately three patrol scrub cycles. In an alternative embodiment, the frequency by which counter 212 is decremented may be based on a different factors and/or a different weighting of factors.

In an alternative embodiment, the decrement event may be based on something other than the patrol scrub. For example, the decrement event may be based on elapsed time (e.g., using a countdown timer). In an embodiment, decrement counter 214 may be programmable. For example, the number of patrol scrubs that trigger a decrement may be dynamically programmed and/or the source of the decrement event may be dynamically programmed.

FIG. 4 is a flow diagram illustrating selected aspects of a memory device anti-aliasing scheme implemented according to an embodiment of the invention. Referring to process block 402, a memory controller (e.g., memory controller 110, shown in FIG. 1) receives a codeword from a rank of memory (e.g., rank 122, shown in FIG. 1). The phrase “receiving a codeword” refers to receiving data and/or ECC code from a rank of memory. In one embodiment, a 72 bit codeword is received from a memory channel wired in a point-to-point arrangement (e.g., a fully-buffered DIMM memory channel). In an alternative embodiment, the codeword may have a different number of bits and may be received from a different type of memory channel.

Referring to process block 404, the memory controller (or another agent) determines whether the rank includes a memory device marked as faulty. For example, the memory controller may determine whether a faulty RAM marker has been set for one or more of the memory devices in the rank. If the rank does include a memory device marked as faulty, then processing of the codeword may proceed as shown in FIG. 5 (e.g., at reference number 502).

Referring to process block 406, the memory controller determines whether the codeword includes a correctable adjacent-symbol-pair-error. A “correctable adjacent-symbol-pair-error” refers to an error in which faulty bits in adjacent symbols are identified. In an embodiment, this determination is based, at least in part, on an error check agent that implements an error correction code (ECC). In an embodiment, if the codeword contains a correctable adjacent-symbol-pair-error, then an error counter associated with the rank that provided the codeword (e.g., counter 212, shown in FIG. 2) is incremented at 408. As used herein, the term “incremented” refers to changing the value of the counter so that it is closer to the threshold value. Thus, “incrementing” can include changing the value of the error counter from one to two, if the threshold is two or more. Similarly, “incrementing” can include changing the value or the error counter from two to one, if the threshold value is, for example, zero.

The memory controller determines whether the error counter value exceeds a threshold at 410. In an embodiment, a two-bit counter is used to implement the counter and the threshold value is three. In an alternative embodiment, a different size counter may be used and/or the threshold value may be different. If the error counter value exceeds the threshold, then a faulty RAM marker is set for the memory device (in the rank) that contains the error as shown by 412.

Referring to process block 414, the memory controller determines whether a decrement counter has exceeded a decrement threshold. For example, the decrement counter may count down from M (e.g., where M may equal 3) to zero. In an embodiment, the magnitude of the decrement threshold is proportional to a periodic read of memory such as a patrol scrub. For example, the magnitude of the decrement threshold may be substantially equal to three patrol scrub cycles.

If the decrement counter exceeds the decrement threshold, then the error counter is decremented at 416. For example, in an embodiment, the decrement counter indicates whether three patrol scrub cycles have occurred. If the patrol scrub cycles have occurred, then the memory controller decrements the error counter at 416. In an alternative embodiment, a different mechanism may be used to decrement the error counter. For example, a countdown timer may be used to control the decrement of the error counter.

As described above, the memory controller may selectively mark a memory device as faulty using, for example, an array of counters and a faulty RAM marker agent. FIG. 5 illustrates selected aspects of processing a codeword having a memory device identified as faulty, according to an embodiment of the invention. Referring to process block 502, the memory controller determines whether a codeword received from a rank of memory contains a correctable error. The term “correctable error” refers to an error that an error correction code (ECC) determines is correctable. The ECC that checks for a correctable error may be based, at least in part, on a Hamming style code, a chip disable style code, or any other suitable error correction code.

If the codeword includes a correctable error, then the memory controller determines whether the correctable error appears in a memory device that is marked as faulty. If so, then the memory controller processes the error as an ECC-correctable error at 506. Processing the error as an ECC-correctable error includes using an ECC to correct the detected error. If not, then the memory controller processes the error as an ECC-uncorrectable error as shown by 508. Processing the error as an ECC-uncorrectable error may include poisoning the codeword and forwarding it the requesting entity (e.g., a processor).

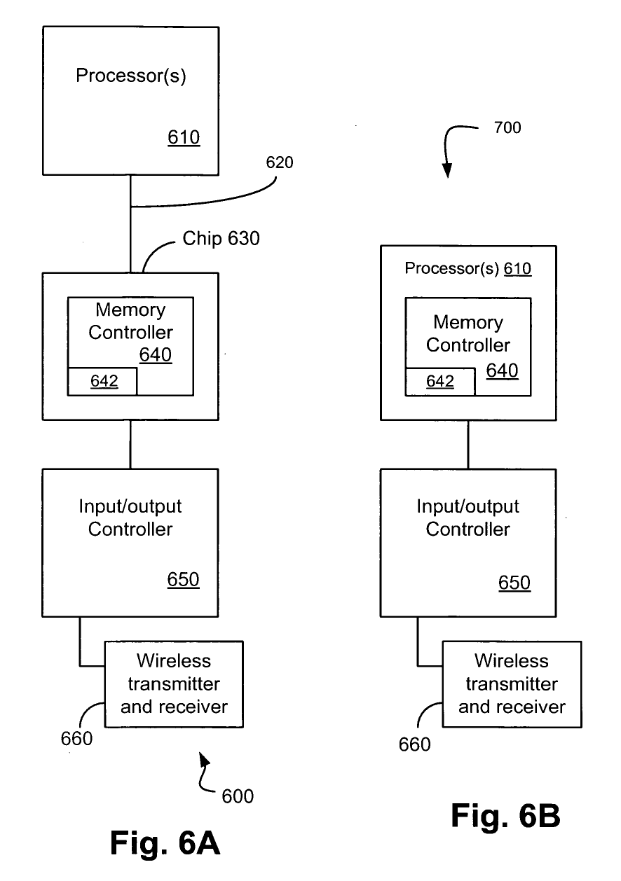

FIGS. 6A and 6B are block diagrams illustrating, respectively, selected aspects of computing systems 600 and 700. Computing system 600 includes processor 610 coupled with an interconnect 620. In some embodiments, the term processor and central processing unit (CPU) may be used interchangeably. In one embodiment, processor 610 is a processor in the XEON® family of processors available from Intel Corporation of Santa Clara, Calif. In an alternative embodiment, other processors may be used. In yet another alternative embodiment, processor 610 may include multiple processor cores.

In one embodiment, chip 630 is a component of a chipset. Interconnect 620 may be a point-to-point interconnect or it may be connected to two or more chips (e.g., of the chipset). Chip 630 includes memory controller 640 which may be coupled with main system memory (e.g., as shown in FIG. 1). In an alternative embodiment, memory controller 640 may be on the same chip as processor 610 as shown in FIG. 6B. In an embodiment, memory device anti-aliasing system 642 uses an array of counters and a faulty memory device marker agent to reduce the frequency of aliasing of memory content errors. For ease of description, anti-aliasing system 642 is shown as a block within memory controller 640. In an alternative embodiment, extended anti-aliasing system 642 may be implemented in a different part of the chipset and/or may be distributed across multiple components of the chipset.

Input/output (I/O) controller 650 controls the flow of data between processor 610 and one or more I/O interfaces (e.g., wired and wireless network interfaces) and/or I/O devices. For example, in the illustrated embodiment, I/O controller 650 controls the flow of data between processor 610 and wireless transmitter and receiver 660. In an alternative embodiment, memory controller 640 and I/O controller 650 may be integrated into a single controller.

Elements of embodiments of the present invention may also be provided as a machine-readable medium for storing the machine-executable instructions. The machine-readable medium may include, but is not limited to, flash memory, optical disks, compact disks-read only memory (CD-ROM), digital versatile/video disks (DVD) ROM, random access memory (RAM), erasable programmable read-only memory (EPROM), electrically erasable programmable read-only memory (EEPROM), magnetic or optical cards, propagation media or other type of machine-readable media suitable for storing electronic instructions. For example, embodiments of the invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

It should be appreciated that reference throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

Similarly, it should be appreciated that in the foregoing description of embodiments of the invention, various features are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed subject matter requires more features than are expressly recited in each claim. Rather, as the following claims reflect, inventive aspects lie in less than all features of a single foregoing disclosed embodiment. Thus, the claims following the detailed description are hereby expressly incorporated into this detailed description.

What is claimed is:

1. An apparatus comprising:
an error check agent to receive a codeword from a rank of memory and to provide an error indication in response to detecting a correctable adjacent-symbol-pair-error in the codeword;
an error counter coupled with the error check agent, the error counter to increment towards a threshold value in response, at least in part, to the error indication from the error check agent; and
a faulty memory device marker agent coupled with the error counter, the faulty memory device marker agent to provide a faulty memory device marker to the error check agent, if the error counter exceeds the threshold value.

2. The apparatus of claim 1, further comprising:
a decrement counter coupled with the error counter, the decrement counter to decrement the error counter responsive, at least in part, to a decrement event.

3. The apparatus of claim 2, wherein the decrement event is proportional to a periodic read of the rank of memory.

4. The apparatus of claim 3, wherein the decrement event is substantially equal to three patrol scrub cycles.

5. The apparatus of claim 4, wherein the threshold value is three.

6. The apparatus of a claim 1, wherein the error check agent is an implementation of an error correction code.

7. The apparatus of claim 6, wherein the error correction code is based, at least in part, on a Hamming style code.

8. The apparatus of claim 1, wherein rank of memory is a rank of dynamic random access memory (DRAM) devices.

9. The apparatus of claim 8, wherein the rank of DRAM devices is a rank of ×8 DRAM devices.

10. The apparatus of claim 9, wherein the correctable adjacent-symbol-pair-error includes any two bit error in adjacent symbols associated with a ×8 DRAM device.

11. A method comprising:
receiving a codeword from a rank of memory;
determining whether the codeword includes a correctable adjacent-symbol-pair-error;
incrementing an error counter associated with the rank of memory, if the codeword includes a correctable adjacent-symbol-pair-error;
determining whether the error counter exceeds an error threshold; and
setting a faulty memory device indicator, if the error counter exceeds the error threshold.

12. The method of claim 11, further comprising:
determining whether a decrement counter exceeds a decrement threshold, if the error counter does not exceed the error threshold; and
decrementing the error counter, if the decrement counter exceeds the decrement threshold.

13. The method of claim 11, wherein receiving the codeword from the rank of memory comprises:
receiving the codeword from a rank of dynamic random access memory (DRAM) devices.

14. The method claim 13, wherein receiving the codeword from the rank of DRAM devices comprises:
receiving the codeword from a rank of a ×8 DRAM devices.

15. The method of claim 11, wherein the error threshold is three.

16. The method of claim 15, wherein the decrement threshold is three.

17. The method of claim 11, wherein determining whether the codeword includes a correctable adjacent-symbol-pair-error comprises:
determining whether the codeword includes a correctable adjacent symbol pair error based, at least in part, on a Hamming style error correction code.

18. A system comprising:
a memory array including at least one rank of memory devices;
an error check agent to receive a codeword from a rank of memory devices and to provide an error indication in response to detecting a correctable adjacent-symbol-pair-error in the rank of memory devices;
for each rank of memory devices, an error counter coupled with error check agent, the error counter to increment towards a threshold value in response to an error indication from the error check agent; and
for each rank of memory devices, a faulty memory device marker agent coupled with error counter, the faulty memory device marker agent to provide a faulty memory device marker to the error check agent, if the error counter exceeds the threshold.

19. The system of claim 18, further comprising:
for each rank of memory devices, a decrement counter coupled with the error counter, the decrement counter to decrement the error counter responsive, at least in part, to a decrement event.

20. The system of claim 18, wherein, for each rank of memory devices the decrement event is proportional to a periodic read of the rank of memory devices.

21. The system of claim 20, wherein the decrement event is substantially equal to three patrol scrub cycles and the threshold value is three.

22. The system of claim 18, wherein the error check agent is an implementation of a Hamming style error correction code.

23. The system of claim 18, wherein the memory array comprises one or more ranks of ×8 dynamic random access memory (DRAM) devices.
